(19) United States
(12) Patent Application Publication
(10) Pub. No.: US 2020/0238332 A1
(43) Pub. Date: Jul. 30, 2020

(54) CROSS-LINKED POLYMERS

(71) Applicant: FLEXENABLE LIMITED, Cambridge (GB)

(72) Inventors: Jan JONGMAN, Cambridge (GB); Herve VANDEKERCKHOVE, Cambridge (GB); Joffrey DURY, Cambridge (GB)

(73) Assignee: FLEXENABLE LIMITED, Cambridge (GB)

(21) Appl. No.: 16/493,574

(22) PCT Filed: Mar. 14, 2018
(86) PCT No.: PCT/EP2018/056439

§ 371 Date: Sep. 12, 2019

(30) Foreign Application Priority Data
Mar. 15, 2017 (GB) 1704102.1

(51) Int. Cl. B05D 3/14; H01L 51/00; H01L 51/05; C09D 4/00; C08K 5/00

(52) U.S. Cl. CPC B05D 3/147; H01L 51/0026; H01L 51/0034; C08F 222/10; C09D 4/00; C08K 5/0025; H01L 2251/10; H01L 51/052

(57) ABSTRACT

A technique comprising: depositing a first layer comprising a precursor to a cross-linked polymer on a substrate comprising at least a semiconductor material that provides one or more semiconductor channels for one or more transistors, wherein said first layer provides at least part of a gate dielectric for said one or more transistors; and exposing the first layer to an argon plasma to produce the cross-linked polymer from the precursor.

The present invention relates to producing cross-linked polymers. Cross-linked polymers typically involves creating bonds between polymer chains, which bonds change one or more properties of the polymer.

One example of the use of cross-linked polymers is in the production of semiconductor devices. The production of semiconductor devices comprising an organic semiconductor material (hereafter referred to as an organic semiconductor device) may comprise depositing a precursor to a cross-linked polymer over the organic semiconductor material and then subjecting the precursor in situ over the organic semiconductor material to a treatment that produces the cross-linked polymer from the precursor. The precursor may, for example, comprise a mixture of a pre-prepared polymer and a cross-linking agent for creating bonds between the polymer chains of the pre-formed polymer. One conventional treatment comprises exposing the precursor to a mercury vapour lamp, but the inventors for the present application have found that this conventional technique can negatively affect the performance of the organic semiconductor device.

The inventors for the present application happened to find that an argon plasma is capable of producing cross-linked polymers from precursors comprising acryloyl and/or methacryloyl cross-linking groups, and also in situ over an organic semiconductor material without excessive negative effects on the semiconductor performance. The surface of the cross-linked polymer which was directly exposed to the argon plasma also did not have an excessive negative effect on the performance of the organic semiconductor device.

Moreover, the inventors for the present application have found that an argon plasma is also capable of achieving cross-linked polymer layers from very thin precursor layers in situ over organic semiconductor materials, such as a gate dielectric layer formed over an organic semiconductor material, without excessive stripping of the precursor. Without wishing to be bound by theory, the inventors for the present application believe that the argon plasma activates the production of a cross-linked polymer in a surface portion of the precursor layer relatively quickly, creating a relatively tough barrier against the stripping action of the plasma while deeper portions of the precursor layer are converted to cross-linked polymer under the action of the plasma.

There is hereby provided a method, comprising: depositing a precursor to a cross-linked polymer on a substrate, the precursor comprising acryloyl and/or methacryloyl groups; and exposing the precursor to radiation generated by an argon plasma to produce the cross-linked polymer.

According to one embodiment, the substrate comprises at least an organic semiconductor material that provides one or more semiconductor channels for one or more transistors.

According to one embodiment, said cross-linked polymer provides at least part of a gate dielectric for said one or more transistors.

According to one embodiment, said precursor comprises a multi-functional acrylate crosslinker.

According to one embodiment, the multi-functional acrylate cross-linker comprises a dipentaertythritol multi-acrylate compound.

According to one embodiment, the multi-functional acrylate cross-linker comprises a dipentaertythritol multi-functional-acrylate.

There is also hereby provided a method comprising: depositing a first layer comprising a precursor to a cross-linked polymer on a substrate comprising at least a semiconductor material that provides one or more semiconductor channels for one or more transistors, wherein said first layer provides at least part of a gate dielectric for said one or more transistors; and exposing the first layer to an argon plasma to produce the cross-linked polymer from the precursor.

Embodiments of the present invention are described in detail hereunder, by way of example only, with reference to the accompanying drawings, in which:

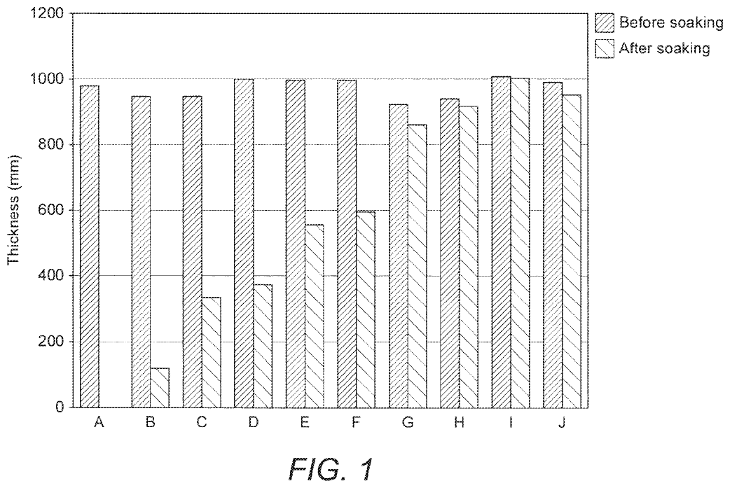

FIG. 1 illustrates the results of experiments for assessing the cross-linking effect of different treatments on one example of a crosslinked polymer precursor comprising acryloyl cross-linking groups;

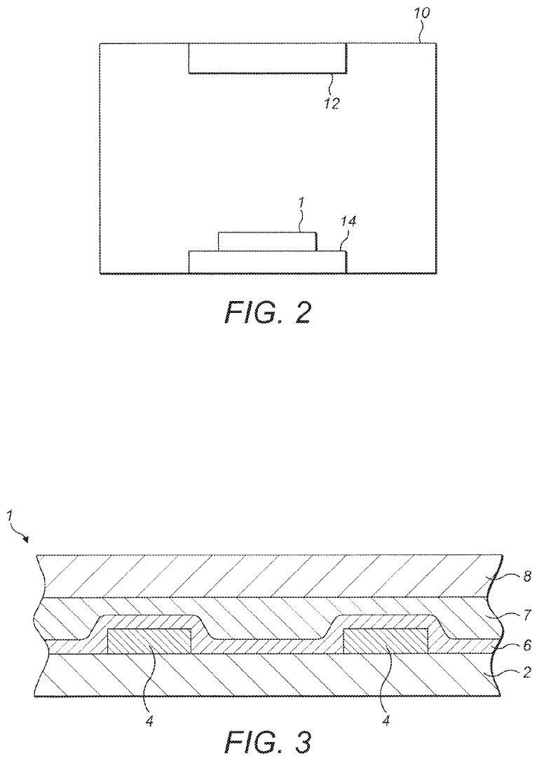

FIG. 2 illustrates a technique of exposing a precursor to a cross-linked polymer to an argon plasma; and

FIG. 3 illustrates a schematic cross-sectional view of one example of a device at an intermediate stage of production, comprising plasma precursor to a cross-linked dielectric polymer.

A number of substantially identical samples were prepared as follows. A thin film of a precursor to a cross-linked dielectric polymer was formed on a glass substrate by spin coating at 700 rpm of a solution of the precursor in propylene glycol methyl ether acetate (PGMEA), followed by baking at 100° C. for about 3 minutes to remove the PGMEA solvent from the film. In this example, the precursor comprised a multi-functional dipentaertythritol acrylate cross-linking agent. Multifunctional dipentaertythritol acrylate cross-linking agents are sold by e.g. PolySciences, Inc. as agents for generating highly cross-linked polymer structures and increasing polymer toughness, modulus and solvent resistance Acrylate functional groups are one example of a class of acrylic cross-linking functional groups including acryloyl groups [CH₂CHC(O)— groups] and/or methacryloyl groups [CH₂C(CH₃)C(O)— groups].

The deposition conditions were chosen to achieve a thickness after baking of about 1000 nm.

The samples were then subjected to different treatments: A-F: exposure to a first type of mercury vapour lamp at different energy densities ranging from 6 J/cm² to 40 J/cm²; G and H: exposure to a second type of mercury vapour lamp for durations of 150 and 170 seconds, respectively; and I and J: exposure to an argon plasma for durations of 10 and 30 seconds, respectively.

Each sample was then subjected to the following soaking treatment. The same solvent (PGMEA) used for film formation by spin-coating was then poured onto the treated polymer film, and allowed to soak into the film for about 2 minutes. The sample was then spun at 1000 rpm for about 60 seconds and thereafter baked for about 3 minutes at about 100° C. The thickness of the layer of material on the glass support substrate was measured before and after the above-described soaking treatment, and FIG. 1 shows the thickness before and after the soaking treatment for each sample.

It can be concluded from the results shown in FIG. 1 that the exposure to argon plasma achieved a cross-linked polymer with a degree of cross-linking at least comparable with the best result achieved with any of the mercury vapour lamps. It can also be concluded from FIG. 1 that a cross-linked polymer with a good degree of cross-linking can be achieved with argon plasma treatment without the plasma causing substantial stripping of the polymer layer. As mentioned above, without wishing to be bound by theory, the inventors for the present application believe that the production of a cross-linked polymer in at least the surface portion of the precursor layer happens faster than any stripping of the precursor material, creating a relatively tough surface barrier which protects the deeper portions of the precursor layer against the stripping action of the argon plasma before they are converted to cross-linked polymer. This surprising result opens the way for using an argon plasma treatment for producing cross-linked dielectric polymers from precursors other than the specific examples described above.

With reference to FIGS. 2 and 3, another sample 1 was prepared by depositing from solution a film 8 of the same cross-linked polymer precursor onto a support film 2 supporting a patterned conductor layer 4 defining the source and drain electrodes of one or more thin film transistors, an organic polymer semiconductor 6 deposited over the patterned conductor layer to provide organic polymer semiconductor channels between the source and drain electrodes of each transistor, and a relatively low dielectric constant (k) gate dielectric layer 7 over the organic polymer semiconductor.

The deposited precursor film 8 was baked to remove the solvent; the film had a thickness between about 400 nm and 1 micron after baking. The sample 1 was mounted on the ground electrode 14 of a Glenn 1000P plasma etcher tool including an Advanced Energy PE1000 power supply operating at 40 kHz, and a programmable logic controller (PLC) controlled user interface. The ground electrode 14 was separated in the plasma chamber 10 from the active electrode 12 by a distance of more than about 10 cm. The plasma etcher tool was configured via the user interface to generate an argon plasma at a partial argon gas pressure of 200 mTorr, and at a relatively low power setting of 500 W for a 39×39 cm² electrode size; and the sample 1 was exposed to the argon plasma for about 180 seconds. Substantial exclusion of molecular oxygen from the plasma chamber 10 during the plasma treatment better prevented undesirable etching of the precursor film, and better prevented the generated radicals undergoing undesirable reactions.

The cross-linked polymer provided a second gate dielectric layer 8 having a higher dielectric constant than the low k gate dielectric layer 7 in contact with the organic semiconductor. It was found by testing that the plasma exposure treatment did not excessively impair the performance of the organic polymer semiconductor, and that the argon plasma exposure treatment causes less reduction in the organic polymer semiconductor performance than a cross-linking treatment using a mercury vapour lamp, for which increased levels of hysteresis were observed.

It was further surprisingly found that the plasma-exposed surface of the cross-linked polymer, which remains in the product semiconductor device where it forms a significant part of the semiconductor device such as e.g. an interface between two gate dielectrics in the region of the semiconductor channels or an interface between a gate dielectric and a metal electrode in the region of the semiconductor channels, did not, over time, excessively impair the performance of the organic polymer semiconductor or the performance of the organic semiconductor device.

Good cross-linking in the uppermost gate dielectric polymer 8 facilitates patterning of further layers over the gate dielectric. For example, good cross-linking in the uppermost gate dielectric polymer facilitates patterning of a gate conductor layer directly on the uppermost gate dielectric polymer 8 by a photolithographic technique using a photoresist material deposited from the same solvent (or same kind of solvent) used to deposit the uppermost gate dielectric layer 8.

The inventors for the present application also found by experiment that at least the radiation generated by the argon plasma plays an important role in achieving the good results described above. Without wishing to be bound by theory, the inventors for the present application believe that the emission spectrum of the argon plasma happens to fit very well with the absorption spectrum of the acrylate cross-linking groups of the precursor; and this surprising finding opens a new way to achieve cross-linked polymers from precursors comprising acrylate cross-linking groups (and related cross-linking groups) over a wide range of applications, not only semiconductor device applications.

In addition to the modifications explicitly mentioned above, it will be evident to a person skilled in the art that various other modifications of the described embodiment may be made within the scope of the invention.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features.

1. A method, comprising: depositing a precursor to a cross-linked polymer on a substrate, the precursor comprising acryloyl and/or methacryloyl groups; and exposing the precursor to radiation generated by an argon plasma to produce the cross-linked polymer.

2. The method according to claim 1, wherein the substrate comprises at least an organic semiconductor material that provides one or more semiconductor channels for one or more transistors.

3. The method according to claim 2, wherein said cross-linked polymer provides at least part of a gate dielectric for said one or more transistors.

4. The method according to claim 1, wherein said precursor comprises a multi-functional acrylate crosslinker.

5. The method according to claim 4, wherein the multi-functional acrylate cross-linker comprises a dipentaertythritol multi-acrylate compound.

6. The method according to claim 5, wherein the multi-functional acrylate cross-linker comprises a dipentaertythritol multi-functional-acrylate.

7. A method comprising: depositing a first layer comprising a precursor to a cross-linked polymer on a substrate comprising at least a semiconductor material that provides one or more semiconductor channels for one or more transistors, wherein said first layer provides at least part of a gate dielectric for said one or more transistors; and exposing the first layer to an argon plasma to produce the cross-linked polymer from the precursor.
